(19) United States
(12) Patent Application Publication
(10) Pub. No.: US 2025/0329404 A1
(43) Pub. Date: Oct. 23, 2025

(54) APPARATUS INCLUDING MULTI-PURPOSE COMMUNICATION MECHANISM AND ASSOCIATED METHODS

(71) Applicant: Micron Technology, Inc., Boise, ID (US)

(72) Inventors: Raymond Chang, Sacramento, CA (US); Shailesh Kayambady Sathyanarayana Bhat, Folsom, CA (US); Raghukiran Sreeramaneni, Frisco, TX (US); Nevil N. Gajera, Meridian, ID (US)

(21) Appl. No.: 19/094,284

(22) Filed: Mar. 28, 2025

Related U.S. Application Data
(60) Provisional application No. 63/635,592, filed on Apr. 17, 2024.

(51) Int. Cl. G11C 29/14; G11C 29/12; G11C 29/38

(52) U.S. Cl. CPC G11C 29/14; G11C 29/12005; G11C 29/38

(57) ABSTRACT

An apparatus including a multi-purpose communication mechanism and associated systems and methods are disclosed herein. The apparatus may include the multi-purpose communication mechanism that enables different circuits to process corresponding/different signals communicated through a shared direct access (DA) pad.

### CROSS-REFERENCE TO RELATED APPLICATION(S)

The present application claims priority to U.S. Provisional Patent Application No. 63/635,592, filed Apr. 17, 2024, the disclosure of which is incorporated herein by reference in its entirety.

### TECHNICAL FIELD

The present technology is directed to apparatuses, such as semiconductor devices including memory and processors, and several embodiments are directed to semiconductor devices that include multi-purpose communication mechanisms.

### BACKGROUND

An apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, reducing power consumption, or reducing manufacturing costs, among other metrics. However, attempts to meet the market demands, such as by reducing the overall device footprint, can often introduce challenges in other aspects, such as for maintaining circuit robustness and/or failure detectability.

### BRIEF DESCRIPTION OF THE DRAWINGS

FIG. 1 is a cross-sectional view of a system-in-package device in accordance with embodiments of the technology.

FIG. 2 is a block diagram of a memory device in accordance with embodiments of the technology.

FIG. 3 is a schematic view of a first example communication configuration in accordance with embodiments of the technology.

FIG. 4 is a schematic view of a second example communication configuration in accordance with embodiments of the technology.

FIG. 5 is a schematic view of a third example communication configuration in accordance with embodiments of the technology.

FIG. 6 is a flow diagram illustrating an example method of operating an apparatus in accordance with an embodiment of the present technology.

FIG. 7 is a block diagram of a system that includes an apparatus configured in accordance with embodiments of the present technology.

### DETAILED DESCRIPTION

As described in greater detail below, the technology disclosed herein relates to an apparatus, such as for memory systems, systems with memory devices, related methods, etc., for facilitating communication of different signals through targeted pins or pads. An apparatus (e.g., a memory device, such as an HBM and/or a RAM, and/or a corresponding system) can be mounted on a silicon interposer along with another apparatus (e.g., a processor). The silicon interposer can be mounted on a package substrate to form a System-in-Package (SiP). The apparatus can include a direct access (DA) pin or pad that is directly connected to an external DA pad and a corresponding bump on the package substrate. Accordingly, the DA pad can be communicatively accessed through the external DA pad by a circuit external to the SiP, thereby allowing the external circuit a direct access (e.g., without communicating through the processor) to the apparatus.

Conventional memory devices (e.g., conventional HBM devices) typically dedicate or reserve the DA pads for testing purposes. As such, the DA pads on the conventional devices remain unused during targeted operations (e.g., post manufacturing operations). Some HBM devices include 40 DA pads according to one or more standards (e.g., JEDEC standards). Since the package substrate is required to provide access to the DA pads on the memory devices, this requires a corresponding number of pads on the package substrate to remain dedicated for only limited (e.g., testing) use. In contrast, technological advances are allowing the SiP and/or the memory devices to provide increasing number of features. Moreover, the technological advances are increasing the demand for additional signals from the SiP. The increasing functionality and demand require additional areas or signal pads on the package substrate without increasing the dimensions of the package substrate.

To facilitate such complex goals, embodiments of the apparatus in accordance with the present technology can include multi-purpose communication mechanism that allows the DA pads to receive two or more signals. For example, an interface die in the HBM can include two or more circuit paths (e.g., a test circuit path and an operating function path) connected in parallel to a common DA pad. The interface die can further include a selection circuit that activates one of the two or more circuit paths according to an operating mode. As an illustrative example, the selection circuit can connect the signals and/or activate (1) the test circuit path for a test mode (e.g., as a validation stage following manufacturing/assembly of the memory device and/or the SiP) or (2) the operating function path for a deployed mode. The parallel connections between the circuit paths can be implemented at or within (1) the interposer, (2) the interface die and before separate interfacing circuits, or (3) the interface die and after a common interfacing circuit.

The multi-purpose communication mechanism can allow the external DA pads to be utilized during deployed operations of the SiP in addition to the testing/validating processes. Accordingly, the multi-purpose communication mechanism can allow the SiP to communicate more functional signals during operation without increasing the dimensions of the package substrate and without increasing the total number of external pads. Moreover, the multi-purpose communication mechanism can be implemented with minimal circuitry (e.g., enable signals, limited number of switches, etc.), thereby maintaining the overall size and circuit complexity for the interface die.

### Example Environment

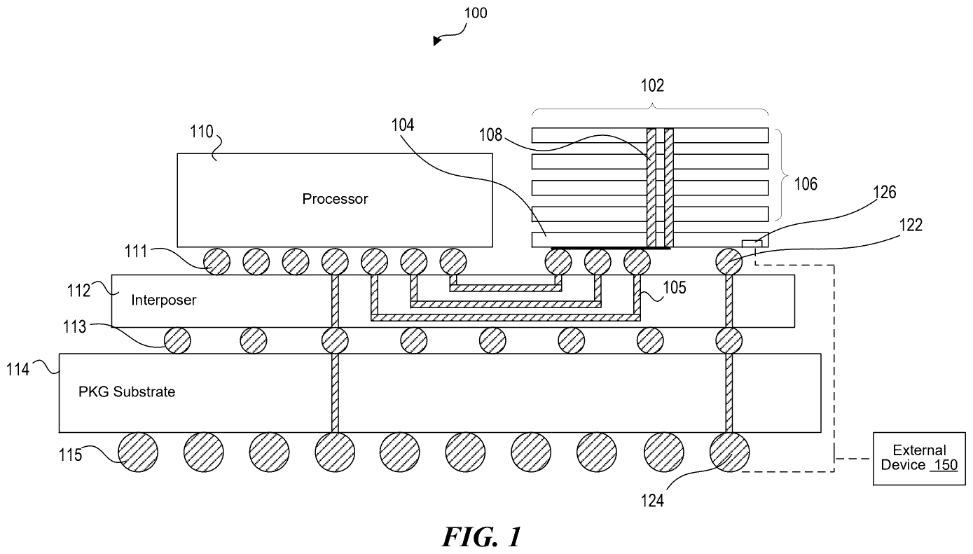

FIG. 1 illustrates a schematic cross-sectional view of a SiP device 100 (i.e., an example apparatus) in accordance with embodiments of the technology. The SiP 100 can include the memory device 102 and the processor 110, which are packaged together on a package substrate 114 along with an interposer 112. The processor 110 may act as a host device of the SiP 100.

In some embodiments, the memory device 102 may be an HBM device that includes an interface die (or logic die) 104 and one or more memory core dies 106 stacked on the interface die 104. The memory device 102 can include one or more through silicon vias (TSVs) 108, which may be used to couple the interface die 104 and the core dies 106.

The interposer 112 (e.g., a silicon interposer) can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. For example, the interposer 112 can include (1) a set of laterally extending connections that communicatively couple the processor 110 and the memory device 102 and (2) a vertically extending via configured to provide direct access (e.g., a direct communicative path without intervening active/passive circuit components) to the memory device 102. Although only three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate may further include direct access (DA) bumps coupled through the package substrate 114 and interposer 112 to the interface die 104.

The memory device 102 can include one or more DA uBumps 122 (e.g., instances of the uBumps 111) configured to provide direct access to targeted circuits, such as self-test or other test/validation circuits, within the memory device 102. Additionally, the memory device 102 can include one or more probe pads 126 that can be used for testing/validation, such as after manufacturing of the memory device 102 and before mounting the memory device 102 on the interposer 112.

The memory device 102 can further include DA external bumps 124 (e.g., instances of the external bumps 115) that are directly connected to the DA uBumps 122 on the memory device 102. In other words, the memory device 102 can include one or more vertical connections that extend through the interposer 112 and the package substrate 114 to directly connect the DA uBumps 122 to the DA external bumps 124. In some embodiments, the vertical connections can provide point-to-point connections that connect a corresponding pairing of one DA uBumps 122 to one DA external bump 124.

The probe pads 126 and the DA uBumps 122 can provide direct access to the memory device 102, such as without having to communicate through other electrical circuits (e.g., the processor 110). In some embodiments, the direct access through the probe pads 126 and the DA uBumps 122 can be used to test or validate the memory device 102. For example, one or more external devices 150 may be connected to the probe pads 126 after manufacturing/attaching the memory device 102 and/or before attaching the memory device 102 to the interposer 112. The external device 150 can be used to test various functionalities and circuits on the memory device 102. Similarly, the external devices 150 or a different tester can be connected to the DA external bumps 124, thereby communicating directly with the memory device 102 through the DA uBumps 122, to test the memory device 102 after it is mounted on the interposer 112, the package substrate 114, or both.

As described in detail below, the memory device 102 can include a multi-purpose communication mechanism configured to facilitate communication of different signals for multiple circuit groups through shared uBumps. In other words, the multi-purpose communication mechanism can enable multiple circuit groupings, such as a test grouping (e.g., a built-in self-test (BIST) circuit, corresponding interface circuit, or the like) and an operating function grouping, to communicate through the same/shared uBump. Accordingly, the multi-purpose communication mechanism can allow the corresponding DA external bumps to be used for communicating different signals according to the operating mode (e.g., test signals for a testing mode and functional signals for an operating mode).

### Example Circuitry

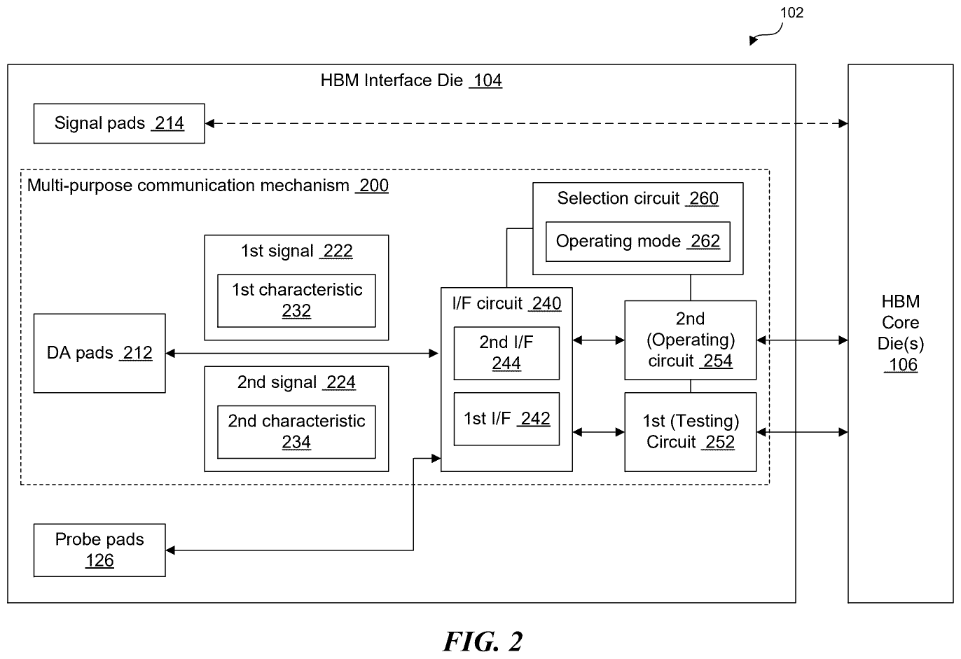

FIG. 2 is a block diagram of a memory device (e.g., the memory device 102 or a portion thereof) in accordance with embodiments of the technology. The memory device 102 can include the interface die 104 and the one or more core dies 106 as described above. For clarity, only a single core die is shown in FIG. 2, however it should be understood that multiple core dies 106 may be coupled to the interface die 104 (e.g., there may be 1-8 or other quantities of core dies 106). The memory device 102 can include a multi-purpose communication mechanism 200 configured to control or facilitate communications through one or more common/shared connection points.

The memory device 102 can include different interface terminals for accessing the core die(s) 106 and/or one or more circuits of the memory. In some embodiments, the different interface terminals can include signal pads 214 along with DA pads 212. The DA pads 212 can correspond to or be attached to the DA uBumps 122 of FIG. 1, and the signal pads 214 can correspond to or be attached to other instances of the uBumps 111 of FIG. 1. The different interface terminals can further include probe pads 126 on the interface die 104 as described above.

The signal pads 214 can be configured to communicate signals associated with functional operations of the memory device 102. The probe pads 126 can be configured to communicate signals associated with specialized operations (e.g., testing operations, such as the self-test function) of the memory device 102. The signal pads 214 and the probe pads 126 can each communicate signals for one operating mode. For example, the signal pads 214 can be utilized during one mode (e.g., during deployed operations), and the probe pads 126 can be utilized during another mode (e.g., testing/validating operations that occur as a part of or at the end of manufacturing).

Unlike the signal pads 214 and the probe pads 126, the DA pads 212 with the multi-purpose communication mechanism 200 can be configured to communicate different signals that are intended for different circuits/modes and/or that have different purposes. For example, the DA pads 212 can be configured to communicate a first set of signals 222 and a second set of signals 224 through the same/shared pads.

The first set of signals 222 can have a corresponding first set of characteristics 232, and the second set of signals 224 can have a corresponding second set of characteristics 234. Each signal characteristic can represent a physical trait or requirement, such as a maximum/minimum voltage, a termination setting, a current setting/limit, a communication frequency, a slew rate requirement, or the like, for the corresponding signal. In some embodiments, the first set of characteristics 232 and the second set of characteristics 234 for signals sharing the same DA pads 212 can match. In other embodiments, the first set of characteristics 232 and the second set of characteristics 234 for signals sharing the same DA pads 212 can be different.

The interface die 104 can include a communication interface circuit 240, such as buffers, transmitters, receivers, or the like, configured to provide the physical requirements for sending and receiving the communicated signals. For the multi-purpose communication mechanism 200, the communication interface circuit 240 can be configured to facilitate different signals, such as the first signals 222 and the second signals 224, that are communicated through the same/shared DA pads 212.

Opposite the DA pads 212, the communication interface circuit 240 can be communicatively coupled to multiple endpoints, such as a first circuit 252 and a second circuit 254. The first circuit 252 can be an endpoint (e.g., a source or a destination) for the first signals 232, and the second circuit 254 can be an endpoint for the second signals 234. For example, the first circuit 252 can include a testing circuitry (e.g., the self-test circuit), and the second circuit 254 can include an operating function circuit configured to provide functions/features during deployed operation of the memory device 102. In some embodiments, based on the overlapping usage/application of the first circuit 252, the communication interface circuit 240 can facilitate the first signal 222 or other similar signals (e.g., testing signals) communicated through the probe pads 126.

For illustrative purposes, the communication interface circuit 240 is described with respect to the first signal 222 and the second signal 224. However, it is understood that the communication interface circuit 240 can facilitate/support the communications through the signal pads 214.

In some embodiments, the communication interface circuit 240 can have separate or dedicate interfacing circuits for each signal path. For example, the communication interface circuit 240 can include a first interface 242 (e.g., a DA interface) for the first circuit 252 and a second interface 244 (e.g., a PHY interface) for the second circuit 254. Accordingly, the first interface 242 can include the circuit (e.g., transmitter, receiver, etc.) configured to facilitate the communication of the first signal 222, and the second interface 244 can include the circuit (e.g., transmitter, receiver, etc.) configured to facilitate the communication of the second signal 224. Both the first interface 242 and the second interface 244 can be connected in parallel to the common/shared DA pads 212. In other words, each shared DA pad can be communicatively connected to a DA circuit (e.g., the first circuit and/or the first interface) and a PHY circuit (e.g., the second circuit and/or the second interface).

The multi-purpose communication mechanism 200 can include a selection circuit 260 that is configured to control the signal routing and/or usage according to an operating mode 262. The operating mode 262 can be designated for the memory device 102 through one or more mode-setting signals that may be received through one of the pads or other mode setting indicators on the interface die 104. For example, the operating mode 262 can indicate a first/testing mode or a second/deployed-operation mode.

The selection circuit 260 can include circuitry that is configured to control operations of the communication interface circuit 240 and/or the endpoint circuits, such as the first circuit 252 and the second circuit 254. The selection circuit 260 can generate a control signal (e.g., a first control signal and a second control signal) that corresponds to the operating mode 262. In some embodiments, the selection circuit 260 can control an enable or an activate signal that allows the input of either the first signal 222 or the second signal 224 at the interface circuit 240, at the endpoint circuits, or both. Along with the enable/activation signal, the selection circuit 260 can include input control components (e.g., AND devices) before or at the first and second circuits that allow the respective first and second signals to be received or passed into the corresponding first and second circuits. Additionally or alternatively, the selection circuit 260 can control a routing switch/path for the first signal 222 or the second signal 224.

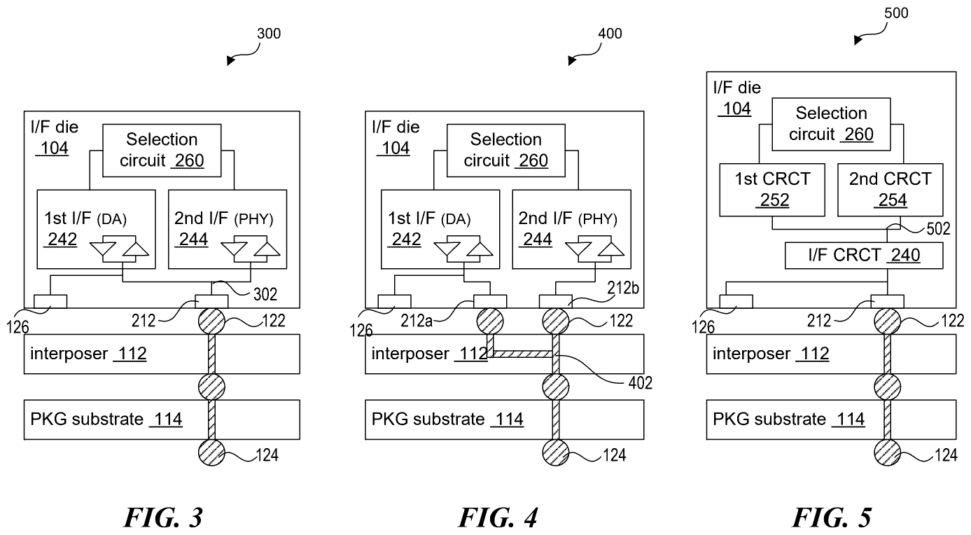

The multi-purpose communication mechanism 200 can have or support different communication configurations. FIGS. 3-5 illustrate different example communication configurations, such as for the parallel connection/path for the DA pads 212 and the first signal 222 and the second signal 224.

FIG. 3 is a schematic view of a first example communication configuration 300 in accordance with embodiments of the technology. The first communication configuration 300 can include a parallel connection 302 within the interface die 104 and between the DA pad 212 and the interface circuit 240 of FIG. 2. For example, the first interface 242 and the second interface 244 can be both connected to the same/shared DA pad 212. In turn, the DA pad 212 can be directly connected to the corresponding DA uBump 122 and DA external bump 124. Accordingly, both the first signal 222 of FIG. 2 and the second signal 224 of FIG. 2 can be communicated to the DA pad 212 through the DA uBump 122 and the DA external bump 124.

For the first communication configuration 300, both the first interface 242 and the second interface 244 can receive the first signal 222 and the second signal 224 through the parallel connection 302. The selection circuit 260 can be configured to control the input/processing at the first interface 242 and the second interface 244, at the first circuit 252 of FIG. 2 and the second circuit 254 of FIG. 2, or both. For example, the selection circuit 260 can generate complementary enable or activate signals to the first interface 242 and the first interface 244 and/or to the first circuit 252 and the second circuit 254. The complementary enable signals can allow either (1) the first circuit 252 and the first interface 242 to communicate through the DA external bump 124 or (2) the second circuit 254 and the second signal 224 to communicate through the DA external bump 124. The selection circuit 260 can enable/activate (1) the first circuit 252 and the first interface 242 to process the first signal 222 for a first operating mode (e.g., the testing/validating mode) and (2) the second circuit 254 and the second signal 224 to process the second signal 224 for a second operating mode (e.g., the deployed operating mode).

Moreover, the internal connection from the probe pad 126 can be tied to the first interface 242. While the probe pad 126 can also be connected to the second interface 244 through the parallel connection 302, the selection circuit 260 can enable/activate the first circuit 252 and the first interface 242 to communicate through the probe pad 126. Accordingly, the selection circuit 260 can prevent the second circuit 254 and the second interface 244 from receiving/processing signals (e.g., the second signal 224) to/from the probe pad 126.

FIG. 4 is a schematic view of a second example communication configuration 400 in accordance with embodiments of the technology. The second communication configuration 400 can include a parallel connection 402 outside of the interface die 104 and within the interposer 112. Accordingly, the interface die 104 can include a first DA pad 212a and a second DA pad 212b. Both DA pads 212a and 212b can be directly connected to the corresponding DA uBump 122 and DA external bump 124. Accordingly, both the first signal 222 of FIG. 2 and the second signal 224 of FIG. 2 can be communicated to the DA pads 212a and 212b.

For the second communication configuration 300, the first interface 242 (e.g., the DA interface) can be directly connected to the first DA pad 212a, and the second interface 244 (e.g., the PHY interface) can be directly connected to the second DA pad 212b. However, given the parallel connection 402, both the first interface 242 and the second interface 244 can receive the first signal 222 and the second signal 224.

Similar to the first communication configuration 300 of FIG. 3, the selection circuit 260 can be configured to control the input/processing at the first interface 242 and the second interface 244, at the first circuit 252 of FIG. 2 and the second circuit 254 of FIG. 2, or both. For example, the selection circuit 260 can generate complementary enable or activate signals to the first interface 242 and the first interface 244 and/or to the first circuit 252 and the second circuit 254. The complementary enable signals can allow either (1) the first circuit 252 and the first interface 242 to communicate through the DA external bump 124 or (2) the second circuit 254 and the second signal 224 to communicate through the DA external bump 124. The selection circuit 260 can enable/activate (1) the first circuit 252 and the first interface 242 to process the first signal 222 for the first operating mode (e.g., the testing/validating mode) and (2) the second circuit 254 and the second signal 224 to process the second signal 224 for the second operating mode (e.g., the deployed operating mode).

The internal connection from the probe pad 126 can be tied to the first interface 242. Since the parallel connection 402 is outside of the interface die 104, the second circuit 254 and the second interface 244 from receiving/processing signals (e.g., the second signal 224) to/from the probe pad 126. Nonetheless, the selection circuit 260 can disable or deactivate the second circuit 254 and the second interface 244 when the probe pad 126 or the corresponding mode (e.g., the testing mode) is in use.

FIG. 5 is a schematic view of a third example communication configuration 500 in accordance with embodiments of the technology. The third communication configuration 500 can include a parallel connection 502 within the interface die 104, between the interface circuit 240 and the endpoint circuits (e.g., the first circuit 252 and the second circuit 254). The interface circuit 240 can provide a common interface (e.g., one shared set of receiver, transmitter, buffer, or a combination thereof) for both the first circuit 252 and the second circuit 254 (e.g., without the separate first interface 242 and second interface 244). In some embodiments, the first signal 222 of FIG. 2 and the second signal 224 of FIG. 2 can have matching signal characteristics that can be supported/facilitated by the common interface.

For the third communication configuration 500, both the first signal 222 and the second signal 224 can be communicated to the first circuit 252 and the second circuit 254. The selection circuit 260 can be configured to control the input/processing at the first circuit 252 and the second circuit 254. For example, the selection circuit 260 can generate complementary enable or activate signals to the first circuit 252 and the second circuit 254. The complementary enable signals can allow either (1) the first circuit 252 to process the received signal or (2) the second circuit 254 to process the received signal. The selection circuit 260 can enable/activate (1) the first circuit 252 to process the first signal 222 for the first operating mode (e.g., the testing/validating mode) and (2) the second circuit 254 to process the second signal 224 for the second operating mode (e.g., the deployed operating mode).

The internal connection from the probe pad 126 can be tied to the common interface circuit 240. As described above, the selection circuit 260 can enable/activate the first circuit 252 to communicate through the probe pad 126. Accordingly, the selection circuit 260 can prevent the second circuit 254 from processing signals (e.g., the second signal 224) to/from the probe pad 126.

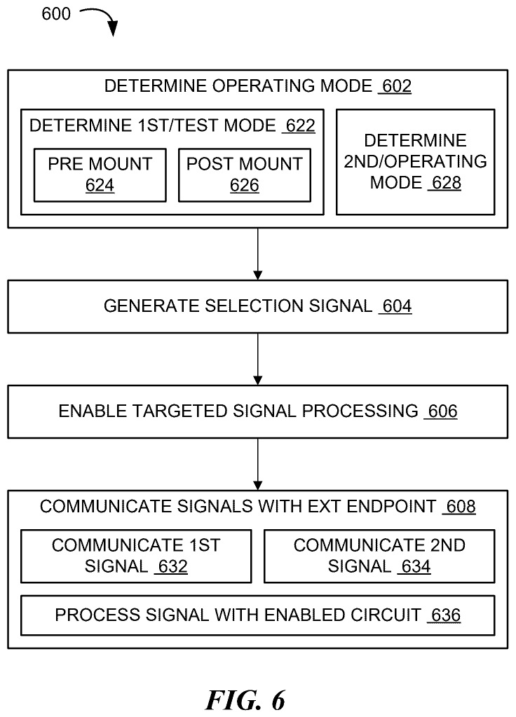

FIG. 6 is a flow diagram illustrating an example method 600 of operating an apparatus (e.g., the SiP 100 of FIG. 1, the memory device 102 of FIG. 1, the interface die 104 of FIG. 2, the multi-purpose communication mechanism 200 of FIG. 2, or a combination thereof) in accordance with an embodiment of the present technology. The method 600 can include facilitating communication of different signals, such as test-related signals and operational signals, through a shared pad/bump according to corresponding operating modes (e.g., a testing mode and a deployed operational mode).

At block 602, the memory device 102 can determine an operating mode (e.g., the operating mode 262 of FIG. 2). The memory device 102 can determine the operating mode based on an input, such as a command provided through the DA pads 212 of FIG. 2 or other pads, a hardware setting (e.g., a switch setting, a pin setting, or the like), or a combination thereof.

In some embodiments, the memory device 102 can determine a first/testing operating mode for the operating mode, such as for testing/validating the memory device 102 as shown in block 622. Further, the memory device 102 can determine the first/testing mode on multiple occasions. For example, as illustrated at block 624, the memory device 102 can determine a pre-mount testing mode corresponding to test/validation of the memory device 102 before it is integrated into the SiP 100. Also, as illustrated at block 626, the memory device 102 can determine a post-mount testing mode corresponding to test/validation of the memory device 102 after it is integrated into the SiP 100.

Further, in determining the operating mode, the memory device 102 can determine a second/deployed operating mode as illustrated at block 628. The memory device 102 can determine the second or deployed operating mode for providing functional operations that occur after testing and/or validating the memory device 102.

At block 604, the memory device 102 can generate one or more selection signals (e.g., enable/activation signals, a switch control signal, or the like) according to the determined operating mode. In some embodiments, the selection circuit 260 of FIG. 2 can generate a first selection signal for enabling the processing of the first signal 222 of FIG. 2 and/or a second selection signal for enabling the processing of the second signal 224 of FIG. 2. The selection circuit 260 can generate the first selection signal based on determining the first/testing mode. The selection circuit 260 can generate the second selection signal based on determining the second/deployed operating mode. The first and second selection signals can be complementary.

At block 606, the memory device 102 can enable signal processing targeted or indicated by the determined operating mode. For example, the selection circuit 260 can communicate the selection signal to the interface circuit 240 of FIG. 2 (e.g., the first interface 242 of FIG. 2 and/or the second interface 244 of FIG. 2), the first circuit 252 of FIG. 2, the second circuit 254, or a combination thereof. The selection circuit 260 can communicate the selection signal to and/or enable (1) the first interface 242, the first circuit 252, or both for the first/testing mode and (2) the second interface 244, the second circuit 254, or both for the second/deployed operation mode. Accordingly, the selection circuit 260 can selectively enable processing of the received signal at the first or second circuits according to the operating mode.

In some embodiments, the selection circuit 260 can include a first input control circuit (e.g., an AND component) located at or before the first circuit 252, the first interface 242, or a combination thereof. Similarly, the selection circuit 260 can include a second input control circuit located at or before the second circuit 254, the second interface 244, or a combination thereof. The input control circuit can control whether the incoming signal is received, passed on, and/or processed by the subsequent circuitry.

Additionally or alternatively, the selection circuit 260 can include a switch that routes the incoming signal according to the selection signal. The switch can be located after the DA pads 212 and before the interface circuit 240 and/or the first/second circuits. Accordingly, the switch can connect the DA pads 212 to either (1) the first circuit 252 and/or the first interface 242 or (2) the second circuit 254 and/or the second interface 244.

Given the complementary configuration of the selection signal and/or the input control circuits, the selection circuit 260 can enable one of the processing paths while disabling the other. For example, for the first/testing mode, the selection circuit 260 can enable the first circuit 252 and/or the first interface 242 while simultaneously disabling the second circuit 254 and/or the second interface 244. Also, for the second/deployed operation mode, the selection circuit 260 can enable the second circuit 254 and/or the second interface 244 while simultaneously disabling the first circuit 252 and/or the first interface 242.

At block 608, the memory device 102 can communicate signals with an external endpoint through a shared portion of a communication path according to the determined operating mode. In some embodiments, the shared portion of the communication path in the memory device 102 can include pads or internal connections (e.g., the parallel connections described above) that connect a combination of the DA pads 212, the probe pad 126, the first and second interfaces, and the first and second circuits.

For example, the memory device 102 can communicate the first signal 222 through the probe pad 126 and across the shared path for the pre-mount testing mode. The memory device 102 can communicate the first signal 222 through the DA pad 212 and across the shared path for the post-mount testing mode. The device 102 can communicate the second signal 224 through the DA pad 212 and across the shared path for the second/deployed operation mode.

At block 632, the memory device 102 can communicate the first signal through the shared pad. At block 634, the memory device 102 can communicate the second signal through the shared pad. In tandem with the communication, the memory device 102 can process the communicated signal with the enabled/targeted circuit as illustrated in block 636. For example, in sending the communication, the first or second circuit can generate the signal that is sent across the shared portion and out of the connected ports (e.g., the probe pad 126 and/or the DA pad 212). Also, in receiving the communication, the communicated signal can be received through the connected ports, conveyed across the shared portion to the enabled/disabled interfaces and/or circuits. Accordingly, the shared portion and/or the shared DA pads 212 can communicate both the first signal 222 and the second signal 224. Beyond the shared communication path/pads, the first circuit 252 can process the first signal 222 separately from the second circuit 254 processing the second signal 224 and according to the operating mode.

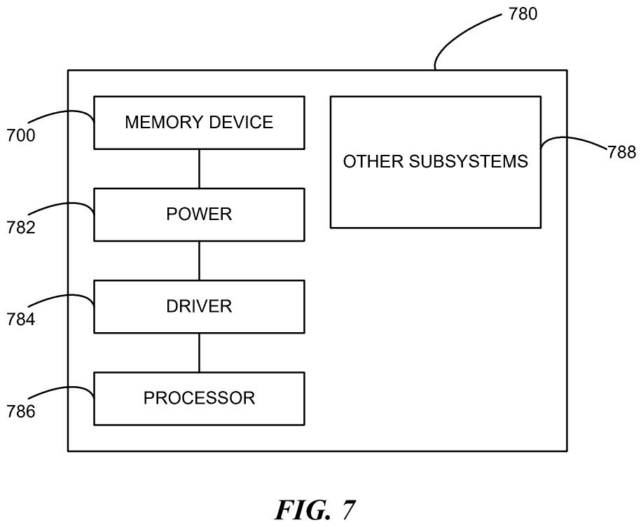

FIG. 7 is a block diagram of a system that includes an apparatus in accordance with embodiments of the present technology. Any one of the foregoing apparatuses (e.g., memory devices) described above with reference to FIGS. 1-6 can be incorporated into or implemented in memory (e.g., a memory device 700) or any of a myriad of larger and/or more complex systems, a representative example of which is system 780 shown schematically in FIG. 7. The system 780 can include the memory device 700, a power source 782, a driver 784, a processor 786, and/or other subsystems or components 788. The memory device 700 can include features generally similar to those of the apparatus described above with reference to FIGS. 1-6 and can therefore include various features for performing a direct read request from a host device. The resulting system 780 can perform any of a wide variety of functions, such as memory storage, data processing, and/or other suitable functions. Accordingly, representative systems 780 can include, without limitation, hand-held devices (e.g., mobile phones, tablets, digital readers, and digital audio players), computers, vehicles, appliances and other products. Components of the system 780 may be housed in a single unit or distributed over multiple, interconnected units (e.g., through a communications network). The components of the system 780 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of HBM and DRAM devices. Apparatuses configured in accordance with other embodiments of the present technology, however, can include other types of suitable storage media in addition to or in lieu of HBM and/or DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-7.

What is claimed is:

1. A System-in-Package (SiP) device, comprising:
an interposer having (1) a set of laterally extending connections and (2) a vertically extending via;
at least one processor mounted on the interposer and connected to the laterally extending connections;
a memory device mounted on the interposer and having:
a set of signal pads connected to the set of laterally extending connections and configured to facilitate communications with the at least one processor,
at least one direct access (DA) pad connected to the vertically extending via and configured to facilitate communication of a first signal and a second signal with an external device, wherein the first signal corresponds to a first operating mode for the memory device and the second signal corresponds to a second operating mode for the memory device,
a first circuit configured to process the first signal for the first operating mode,
a second circuit configured to process the second signal for the second operating mode, and
a multi-purpose communication mechanism configured to selectively enable processing of (1) the first signal at the first circuit when the memory device is in the first operating mode and (2) the second signal at the second circuit when the memory device is in the second operating mode.

2. The SiP device of claim 1, wherein the memory device is a high bandwidth memory (HBM) having a set of core dies stacked on an interface die, wherein the interface die includes at least the set of signal pads, the at least one DA pad, and the multi-purpose communication mechanism.

3. The SiP device of claim 2, wherein:
the first operating mode is a testing mode for validating functional operations of the HBM;
the first signal includes a test input, a test command, a test result, or a combination thereof; and
the first circuit includes a self-test circuit.

4. The SiP device of claim 3, wherein the HBM further includes a probe pad communicatively coupled to the first circuit and configured to provide direct access to the self-test circuit for the testing mode that occurs before the HBM is mounted on the interposer.

5. The SiP device of claim 3, further comprising:
a package substrate having the interposer mounted thereon and configured to provide external communication interface for the SiP, the package substrate having a DA external bump opposite the interposer and communicatively coupled to the DA pad on the HBM, wherein the DA external bump is for facilitating the communication of the first signal during the testing mode and the second signal during the second mode.

6. The SiP device of claim 5, wherein the second operating mode is a deployed operation mode for providing functional operations that occur after testing and/or validating the HBM.

7. The SiP device of claim 1, wherein:
the memory device includes:
a first interface including a receiver, a transmitter, or both configured to communicate the first signal to/from the first circuit, wherein the first interface is connected to the DA pad;
a second interface including a receiver, a transmitter, or both configured to communicate the second signal to/from the second circuit, wherein the second interface is connected within the memory device to the DA pad and the first interface;
a probe pad connected within the memory device to the first interface, the second interface, and the DA pad; and
the multi-purpose communication mechanism is configured to enable or activate (1) the first interface, the first circuit, or both for the first mode and (2) the second interface, the second circuit, or both for the second mode.

8. The SiP device of claim 1, wherein:
the DA pad is a first DA pad;
the memory device includes:
a second DA pad;
a first interface including a receiver, a transmitter, or both configured to communicate the first signal to/from the first circuit, wherein the first interface is connected to the first DA pad;
a second interface including a receiver, a transmitter, or both configured to communicate the second signal to/from the second circuit, wherein the second interface is connected to the second DA pad;
a probe pad connected within the memory device to the first interface and the first DA pad;
the interposer includes a parallel connection for providing the first and second signals to both the first DA pad and the second DA pad; and
the multi-purpose communication mechanism is configured to enable or activate (1) the first interface, the first circuit, or both for the first mode and (2) the second interface, the second circuit, or both for the second mode.

9. The SiP device of claim 1, wherein:
the memory device includes:
a common interface including a receiver, a transmitter, or both configured to communicate the first and second signals to/from both the first and second circuit, wherein the common interface is connected to the DA pad;
a probe pad connected within the memory device to the DA pad and the common interface; and
the multi-purpose communication mechanism is configured to enable or activate (1) the first circuit for the first mode and (2) the second circuit for the second mode.

10. The SiP device of claim 1, wherein the multi-purpose communication mechanism is configured selectively enable processing based on generating (1) a first selection signal for enabling the processing of the first signal and (2) a second selection signal for enabling the processing of the second signal, wherein the first and second selection signals are complementary.

11. The SiP device of claim 10, wherein the multi-purpose communication mechanism includes:
a first input control circuit located at or before the first circuit and configured to allow the first signal into the first circuit according to the first selection signal; and
a second input control circuit located at or before the second circuit and configured to allow the second signal into the second circuit according to the second selection signal.

12. The SiP device of claim 1, wherein the multi-purpose communication mechanism includes a switch configured to electrically couple the DA pad to (1) the first circuit for the first operating mode and (2) the second circuit for the second operating mode.

13. A High-Bandwidth Memory (HBM), comprising:
at least one core die;
an interface die with the at least one core die stacked thereon, the interface die including:
a first functional circuit configured to process a first signal for a first operating mode of the HBM;
a second functional circuit configured to process a second signal for a second operating mode of the HBM;
a direct access (DA) pad communicatively coupled to both the first and second functional circuits and configured to communicate both the first and second signals to/from an external device; and
a multi-purpose communication mechanism configured to selectively enable processing of (1) the first signal at the first circuit when the HBM is in the first operating mode and (2) the second signal at the second circuit when the memory device is in the second operating mode.

14. The HBM of claim 13, wherein:
the first mode is a testing mode for testing the HBM during or after manufacture of the HBM;
the second mode is a deployed operation mode for providing functional operations that occur after testing and manufacturing the HBM.

15. The HBM of claim 14, further comprising:
a DA interface circuit configured to facilitate a physical layer communication of the first signal between the DA pad and the first circuit;
a physical layer circuit configured to facilitate a physical layer communication of the second signal between the DA pad and the second circuit; and
a probe pad connected within the memory device to the DA interface circuit, the physical layer circuit, and the DA pad;
wherein:
the multi-purpose communication mechanism is configured to enable or activate (1) the first interface, the first circuit, or both for the testing mode and (2) the second interface, the second circuit, or both for the deployed operation mode.

16. The HBM of claim 14, wherein:
the DA pad is a first DA pad configured to communicate both the first and second signals; and
the multi-purpose communication mechanism is configured to enable or activate (1) the first interface, the first circuit, or both for the testing mode and (2) the second interface, the second circuit, or both for the deployed operation mode;
the HBM further comprising:
a second DA pad configured to communicate both the first and second signals;
a DA interface circuit configured to facilitate a physical layer communication of the first signal between the first DA pad and the first circuit;
a physical layer circuit configured to facilitate a physical layer communication of the second signal between the second DA pad and the second circuit; and
a probe pad connected within the memory device to the first interface and the first DA pad.

17. The HBM of claim 14, further comprising:
a common interface circuit configured to facilitate, at a physical layer, communication of the first and second signals between the DA pad and both the first and second circuits;
a probe pad connected within the memory device to the DA pad and the common interface, wherein the probe pad is for facilitating the testing mode before the HBM is integrated into a System-in-Package (SiP), wherein the DA pad is for facilitating the testing mode after the HBM is integrated into the SiP; and
wherein:
the multi-purpose communication mechanism is configured to enable or activate (1) the first circuit for the testing mode and (2) the second circuit for the deployed operation mode.

18. A method of operating a High-Bandwidth Memory (HBM), the method comprising:
determining a testing mode for the HBM;
receiving a first signal through a direct access (DA) pad;
processing the first signal at a first circuit for the testing mode;
determining a deployed operation mode for the HBM after the testing mode;
receiving a second signal through the same DA pad; and
processing the second signal at a second circuit for the deployed operation mode.

19. The method of claim 18, further comprising:
determining a first instance of the testing mode validating the HBM before integration into a System-in-Package (SiP), wherein:
the testing mode is a second instance of the testing mode for validating the HBM after the integration into the SiP;
the first signal is for directly communicating between an external device and the HBM within the SiP; and
the first signal is processed at the first circuit for the first and second instances of the testing mode.

20. The method of claim 18, wherein:
processing the first signal at the first circuit includes enabling the first circuit while disabling the second circuit during the testing mode; and
processing the second signal at the second circuit includes enabling the second circuit while disabling the first circuit during the deployed operation mode.
